(19) United States
(12) Patent Application Publication
(10) Pub. No.: US 2023/0081981 A1
(43) Pub. Date: Mar. 16, 2023

(54) SEMICONDUCTOR DEVICE MANUFACTURING METHOD AND SEMICONDUCTOR DEVICE

(71) Applicant: KABUSHIKI KAISHA TOSHIBA, Tokyo (JP)

(72) Inventor: Tatsuo SHIMIZU, Shinagawa (JP)

(73) Assignee: KABUSHIKI KAISHA TOSHIBA, Tokyo (JP)

(21) Appl. No.: 17/653,173

(22) Filed: Mar. 2, 2022

(30) Foreign Application Priority Data
Sep. 16, 2021 (JP) 2021-150895

(51) Int. Cl. H01L 21/265; H01L 29/20; H01L 29/207

(52) U.S. Cl. CPC H01L 21/26546; H01L 29/2003; H01L 29/207

(57) ABSTRACT

A semiconductor device manufacturing method of embodiments includes: performing first ion implantation implanting an element of either carbon (C) or oxygen (O) into a nitride semiconductor layer; performing second ion implantation implanting hydrogen (H) into the nitride semiconductor layer; forming a coating layer on a surface of the nitride semiconductor layer; performing a first heat treatment; removing the coating layer; and performing a second heat treatment.

### CROSS-REFERENCE TO RELATED APPLICATION

This application is based upon and claims the benefit of priority from Japanese Patent Application No. 2021-150895, filed on Sep. 16, 2021, the entire contents of which are incorporated herein by reference.

### FIELD

Embodiments described herein relate generally to a semiconductor device manufacturing method and a semiconductor device.

### BACKGROUND

Semiconductor elements such as transistors and diodes are used in circuits such as switching power supply circuits and inverter circuits. These semiconductor elements are required to have high breakdown voltage and low on-resistance. The relationship between the breakdown voltage and the on-resistance is a trade-off relationship determined by semiconductor material.

Due to advances in technological development, semiconductor devices have achieved low on-resistance close to the limit of silicon, which is a major semiconductor material. In order to further increase the breakdown voltage or further reduce the on-resistance, it is necessary to change the semiconductor material. By using a nitride semiconductor, such as gallium nitride or aluminum gallium nitride, as the semiconductor material of the semiconductor element, the trade-off relationship determined by the semiconductor material can be improved. Therefore, it is possible to dramatically increase the breakdown voltage and reduce the on-resistance of the semiconductor element.

When a semiconductor element is formed using a nitride semiconductor, it is desired to locally form a p-type impurity region or an n-type impurity region at a desired position of the nitride semiconductor by using an ion implantation method. By locally forming the p-type impurity region or the n-type impurity region by using the ion implantation method, it becomes easy to improve the performance of the semiconductor element and reduce the cost of the semiconductor element.

### BRIEF DESCRIPTION OF THE DRAWINGS

FIG. 1 is a diagram showing the manufacturing flow of a semiconductor device manufacturing method of a first embodiment;

FIG. 2 is a schematic cross-sectional view showing the semiconductor device manufacturing method of the first embodiment;

FIG. 3 is a schematic cross-sectional view showing the semiconductor device manufacturing method of the first embodiment;

FIG. 4 is a schematic cross-sectional view showing the semiconductor device manufacturing method of the first embodiment;

FIG. 5 is a schematic cross-sectional view showing the semiconductor device manufacturing method of the first embodiment;

FIG. 6 is a schematic cross-sectional view showing the semiconductor device manufacturing method of the first embodiment;

FIG. 7 is a schematic cross-sectional view showing the semiconductor device manufacturing method of the first embodiment;

FIG. 8 is a schematic cross-sectional view showing the semiconductor device manufacturing method of the first embodiment;

FIG. 9 is a schematic cross-sectional view showing the semiconductor device manufacturing method of the first embodiment;

FIGS. 10A, 10B, and 10C are explanatory diagrams of the function and effect of the semiconductor device manufacturing method of the first embodiment;

FIG. 11 is a diagram showing the manufacturing flow of a semiconductor device manufacturing method of a second embodiment;

FIG. 12 is a diagram showing the manufacturing flow of a semiconductor device manufacturing method of a third embodiment;

FIG. 13 is a cross-sectional view showing a semiconductor device manufacturing method of a fourth embodiment;

FIG. 14 is a cross-sectional view showing the semiconductor device manufacturing method of the fourth embodiment;

FIGS. 15A and 15B are explanatory diagrams of the function and effect of the semiconductor device manufacturing method of the fourth embodiment;

FIG. 16 is a schematic cross-sectional view of a semiconductor device of a fifth embodiment;

FIG. 17 is a schematic cross-sectional view of a semiconductor device of a sixth embodiment;

FIG. 18 is a schematic cross-sectional view of a semiconductor device of a seventh embodiment; and

FIG. 19 is a schematic cross-sectional view of a semiconductor device of an eighth embodiment.

### DETAILED DESCRIPTION

A semiconductor device manufacturing method of embodiments includes: performing first ion implantation implanting an element of either carbon (C) or oxygen (O) into a nitride semiconductor layer; performing second ion implantation implanting hydrogen (H) into the nitride semiconductor layer; forming a coating layer on a surface of the nitride semiconductor layer; performing a first heat treatment; removing the coating layer; and performing a second heat treatment.

Hereinafter, embodiments will be described with reference to the diagrams. In the following description, the same or similar members may be denoted by the same reference numerals, and the description of the members once described may be omitted.

In this specification, the “nitride semiconductor layer” contains a “GaN-based semiconductor”. The “GaN-based semiconductor” is a general term for gallium nitride (GaN), aluminum nitride (AlN), indium nitride (InN), and semiconductors having an intermediate composition thereof.

In this specification, “undoped” means that the impurity concentration is equal to or less than 1×10¹⁵ cm⁻³.

In this specification, in order to show the positional relationship of components and the like, the upper direction of the diagram is described as “upper” and the lower direction of the diagram is described as “lower”. In this specification, the concepts of “upper” and “lower” do not necessarily indicate the relationship with the direction of gravity.

In addition, in the following description, when there are notations of n⁺, n, n⁻, p⁺, p, and p⁻, these indicate the relative high and low of the impurity concentration in each conductive type. That is, indicates that the n-type impurity concentration is relatively higher than n, and n⁻ indicates that the n-type impurity concentration is relatively lower than n. In addition, indicates that the p-type impurity concentration is relatively higher than p, and p⁻ indicates that the p-type impurity concentration is relatively lower than p. In addition, n⁺-type and n⁻-type may be simply described as n-type, p⁺-type and p⁻-type may be simply described as p-type.

### First Embodiment

A semiconductor device manufacturing method of a first embodiment includes: performing first ion implantation for implanting an element of either carbon (C) or oxygen (O) into a nitride semiconductor layer; performing second ion implantation for implanting hydrogen (H) into the nitride semiconductor layer; forming a coating layer on a surface of the nitride semiconductor layer;

performing a first heat treatment; removing the coating layer; and performing a second heat treatment.

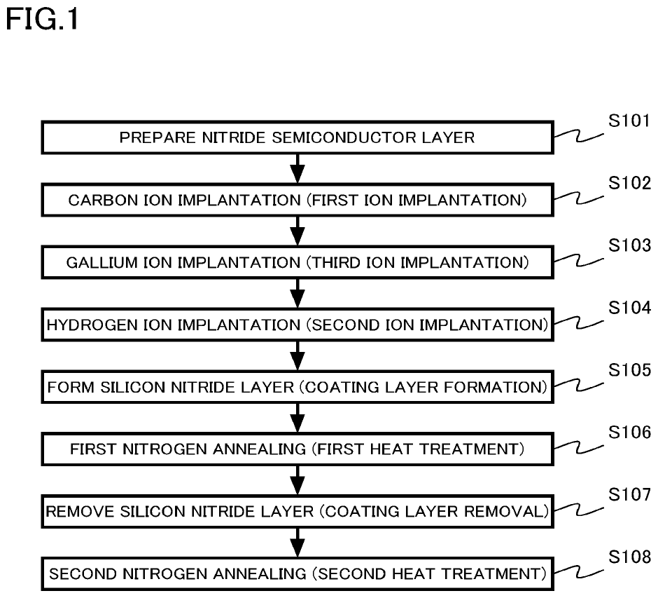

FIG. 1 is a diagram showing the manufacturing flow of the semiconductor device manufacturing method of the first embodiment. The semiconductor device manufactured by the semiconductor device manufacturing method of the first embodiment includes a nitride semiconductor layer having a p-type impurity region.

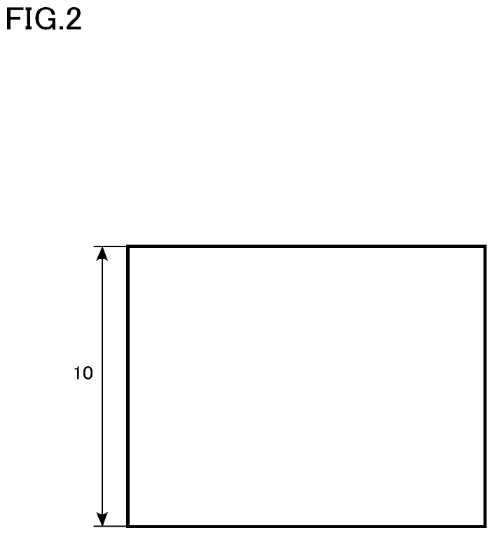

FIGS. 2 to 9 are cross-sectional views showing the semiconductor device manufacturing method of the first embodiment.

The semiconductor device manufacturing method of the first embodiment includes a nitride semiconductor layer preparation step S101, a carbon ion implantation step S102 (first ion implantation), a gallium ion implantation step S103 (third ion implantation), a hydrogen ion implantation step S104 (second ion implantation), a silicon nitride layer formation step S105 (coating layer formation), a first nitrogen annealing step S106 (first heat treatment), a silicon nitride layer removal step S107 (coating layer removal), and a second nitrogen annealing step S108 (second heat treatment).

First, a nitride semiconductor layer 10 is prepared (S101: FIG. 2). The nitride semiconductor layer 10 is a GaN-based semiconductor. Hereinafter, a case where the nitride semiconductor layer 10 is gallium nitride (GaN) will be described as an example.

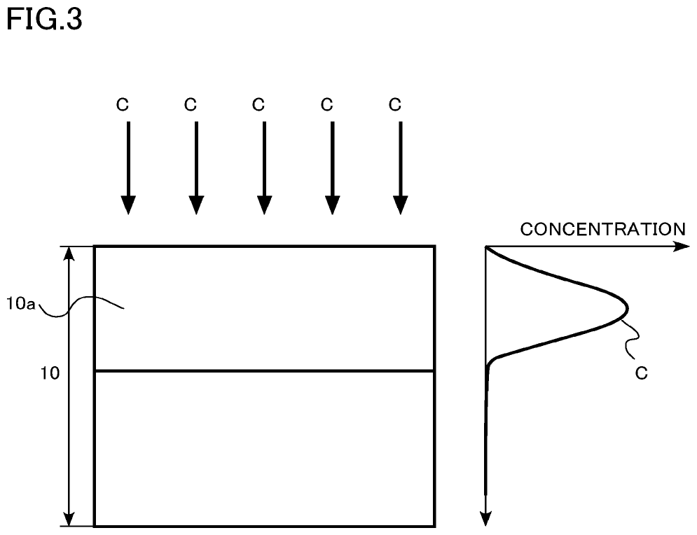

Then, carbon (C) is ion-implanted onto the surface of the nitride semiconductor layer 10 by using a known ion implantation method (S102: FIG. 3). Carbon ion implantation corresponds to the first ion implantation.

By ion-implanting carbon, an impurity region 10a is formed in the nitride semiconductor layer 10. For example, carbon may be ion-implanted multiple times with different ion implantation energies.

The dose amount of carbon is, for example, equal to or more than 1×10¹¹ cm⁻² and equal to or less than 1×10¹⁵ cm⁻². FIG. 3 also shows the carbon concentration distribution in the depth direction. The carbon concentration distribution is controlled by adjusting the ion implantation energy, the dose amount, and the number of ion implantations at the time of carbon ion implantation.

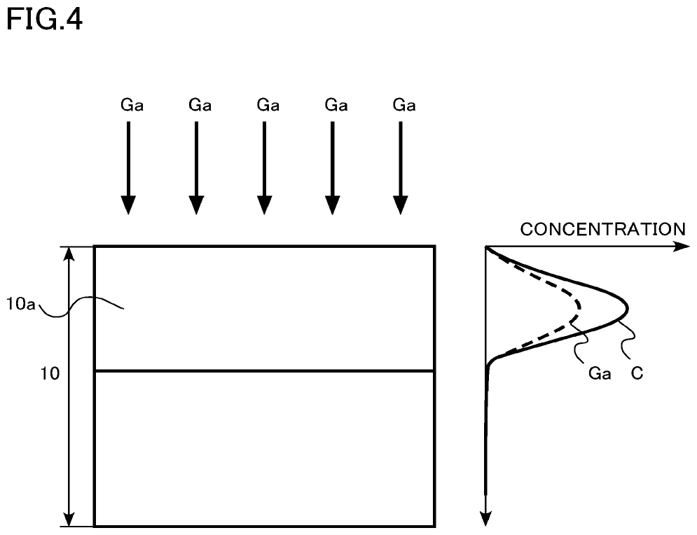

Then, gallium (Ga) is ion-implanted onto the surface of the nitride semiconductor layer 10 by using a known ion implantation method (S103: FIG. 4). Ion implantation of gallium corresponds to the third ion implantation.

Gallium is introduced into the impurity region 10a. For example, gallium may be ion-implanted multiple times with different ion implantation energies.

The dose amount of gallium is, for example, less than the dose amount of carbon. The dose amount of gallium is, for example, equal to or more than 1×10¹¹ cm⁻² and equal to or less than 1×10¹⁵ cm^{×2}.

FIG. 4 also shows the gallium concentration distribution in the depth direction immediately after gallium ion implantation. As shown in FIG. 4, for example, the gallium concentration distribution formed by the third ion implantation is formed so as to be included in the carbon concentration distribution formed by the first ion implantation. In other words, for example, in the impurity region 10a, the gallium concentration at an arbitrary position in the depth direction is lower than the carbon concentration. The gallium concentration distribution is controlled by adjusting the ion implantation energy, the dose amount, and the number of ion implantations at the time of gallium ion implantation.

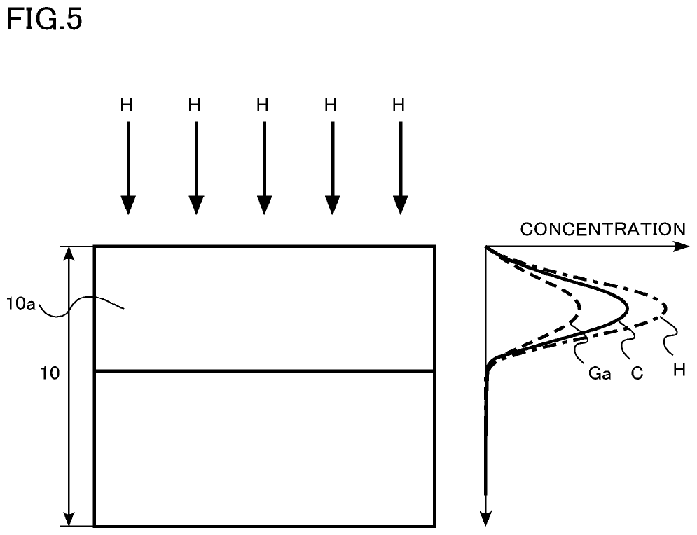

Then, hydrogen (H) is ion-implanted onto the surface of the nitride semiconductor layer 10 by using a known ion implantation method (S104: FIG. 5). Ion implantation of hydrogen corresponds to the second ion implantation.

Hydrogen is introduced into the impurity region 10a. For example, hydrogen may be ion-implanted multiple times with different ion implantation energies.

The dose amount of hydrogen in the second ion implantation is, for example, greater than the dose amount of carbon in the first ion implantation. The dose amount of hydrogen in the second ion implantation is, for example, greater than the dose amount of gallium in the third ion implantation. The dose amount of hydrogen is, for example, equal to or more than 1×10¹⁵ cm⁻² and equal to or less than 1×10¹⁶ cm⁻².

FIG. 5 also shows the hydrogen concentration distribution in the depth direction immediately after hydrogen ion implantation. As shown in FIG. 5, for example, the hydrogen concentration distribution formed by the second ion implantation is formed so as to include the carbon concentration distribution formed by the first ion implantation and include the gallium concentration distribution formed by the third ion implantation. In other words, for example, in the impurity region 10a, the hydrogen concentration at an arbitrary position in the depth direction is higher than the carbon concentration and the gallium concentration. The hydrogen concentration distribution is controlled by adjusting the ion implantation energy, the dose amount, and the number of ion implantations at the time of hydrogen ion implantation.

The order of the first ion implantation, the second ion implantation, and the third ion implantation may be changed.

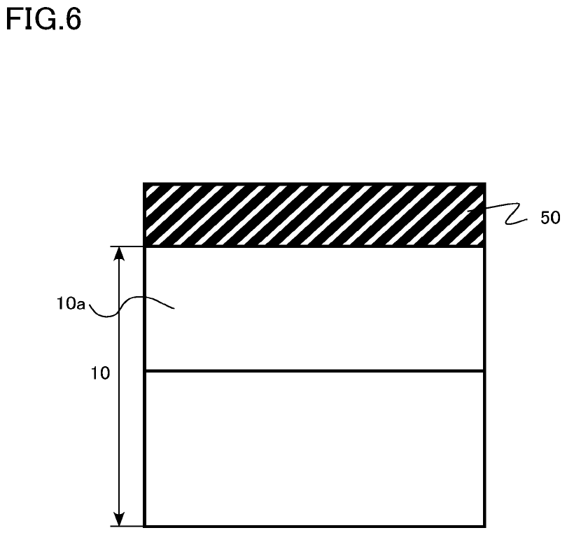

Then, a silicon nitride layer 50 is formed on the surface of the nitride semiconductor layer 10 by using a known film growth method (S105: FIG. 6). The silicon nitride layer 50 is an example of a coating layer. The coating layer is not limited to silicon nitride.

The coating layer is, for example, an insulator. The coating layer is, for example, silicon oxide, silicon nitride, silicon oxynitride, or aluminum nitride.

The coating layer is, for example, a conductor or a semiconductor. The coating layer is, for example, polycrystalline silicon.

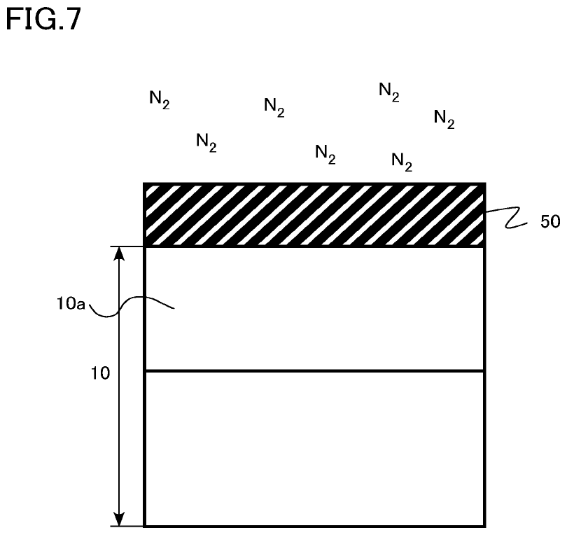

Then, first nitrogen annealing is performed (S106: FIG. 7). The first nitrogen annealing is performed, for example, in a nitrogen gas atmosphere under the conditions of temperature equal to or more than 900° C. and equal to or less than 1250° C. The first nitrogen annealing is an example of the first heat treatment.

The first heat treatment is performed in a non-oxidizing atmosphere containing argon, nitrogen, hydrogen, or helium, for example.

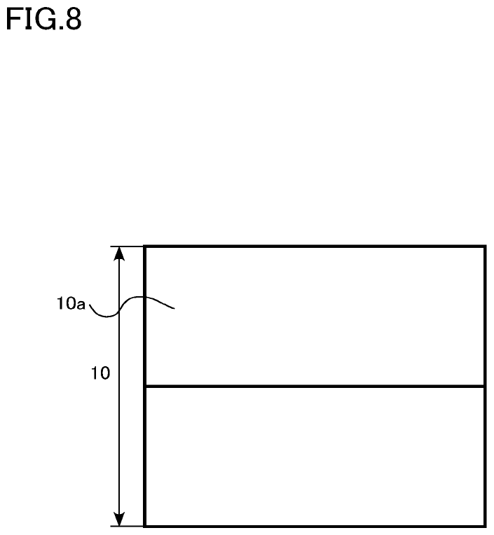

Then, the silicon nitride layer 50 on the surface of the nitride semiconductor layer 10 is removing by using a known wet etching method (S107: FIG. 8). The surface of the nitride semiconductor layer 10 is exposed.

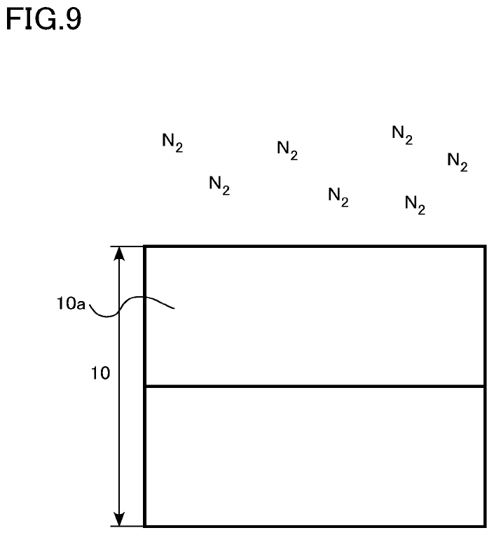

Then, second nitrogen annealing is performed (S108: FIG. 9). The second nitrogen annealing is performed, for example, in a nitrogen gas atmosphere under the conditions of temperature equal to or more than 900° C. and equal to or less than 1250° C. The second nitrogen annealing is an example of the second heat treatment.

The second heat treatment is performed in a non-oxidizing atmosphere containing argon, nitrogen, or helium, for example. The second heat treatment is performed, for example, in an atmosphere containing no hydrogen.

By the above-described semiconductor device manufacturing method, the nitride semiconductor layer 10 having the impurity region 10a is formed. The impurity region 10a is a p-type nitride semiconductor region in which carbon, which is a conductive impurity, is activated. The impurity region 10a is a p-type impurity region containing carbon. The carbon concentration of the impurity region 10a is, for example, equal to or more than 1×10¹⁶ cm⁻³.

Hereinafter, the function and effect of the semiconductor device manufacturing method of the first embodiment will be described.

When a semiconductor element is formed using a nitride semiconductor, it is desired to locally form a p-type impurity region or an n-type impurity region at a desired position of the nitride semiconductor by using the ion implantation method. By locally forming the p-type impurity region or the n-type impurity region by using the ion implantation method, it becomes easy to improve the performance of the semiconductor element and reduce the cost of the semiconductor element.

However, it is difficult to form a low-resistance conductive impurity region simply by ion-implanting p-type or n-type conductive impurities into nitride semiconductor and performing heat treatment. This is because it is difficult to increase the activation rate of conductive impurities by heat treatment.

According to the semiconductor device manufacturing method of the first embodiment, it is possible to form a low-resistance conductive impurity region by increasing the activation rate of conductive impurities. The details will be described below.

Carbon in gallium nitride is energetically more stable when the carbon enters the nitrogen site than when the carbon enters the gallium site in an ideal state in which there are no defects, such as vacancies or interstitial atoms. Carbon enters the nitrogen site of gallium nitride to function as a p-type impurity, that is, an acceptor.

However, even if carbon is introduced into gallium nitride, there is a problem that the electrical resistance of the p-type impurity region containing carbon does not decrease since the activation rate of carbon as an acceptor does not increase. One reason for this problem is considered to be that a part of the carbon introduced into gallium nitride enters the gallium site.

Carbon enters the gallium site of gallium nitride to function as an n-type impurity, that is, a donor. Therefore, the activation rate of carbon as an acceptor is considered to be low eventually. The reason why carbon enters the gallium site instead of the nitrogen site is considered to be, for example, the presence of gallium vacancies in gallium nitride. In addition, it is considered that when the carbon of N site, which is a p-type impurity, is formed, self-compensation is likely to occur in which carbon of Ga site, which is an n-type impurity, is formed at the same time. In this embodiment, in order to pass through inert hydrogen-bonded carbon (H-bonded C) when making a p-type impurity, it is possible to finally form the carbon of N site, which is a p-type impurity, without causing self-compensation.

In order to reduce the electrical resistance of the p-type impurity region containing carbon, it is necessary to increase the percentage of carbon entering the nitrogen site of gallium nitride by suppressing carbon from entering the gallium site of gallium nitride.

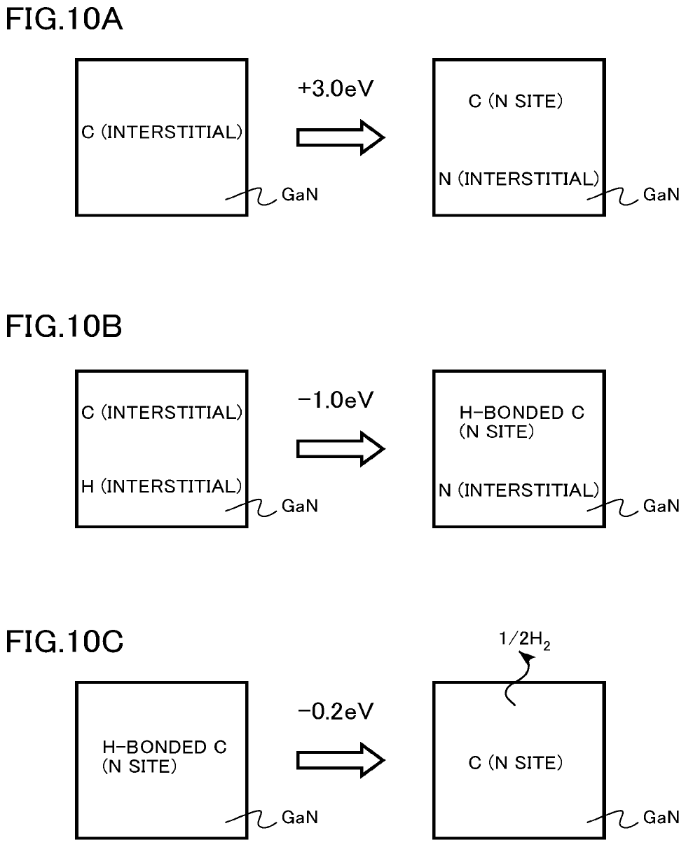

FIGS. 10A, 10B, and 10C are explanatory diagrams of the function and effect of the semiconductor device manufacturing method of the first embodiment. FIGS. 10A, 10B, and 10C are diagrams showing the results of energy calculation in various states in which carbon is present in gallium nitride (GaN). The calculation of the energy in various states is performed by the first principle calculation.

FIG. 10A is a diagram for energy difference comparison between a state in which carbon (C) is present at the interstitial position of gallium nitride (GaN) (left diagram) and a state in which carbon (C) entering the nitrogen site and nitrogen (N) present at the interstitial position coexist (right diagram). Hereinafter, the carbon present at the interstitial position is also referred to as interstitial carbon, and the nitrogen present at the interstitial position is also referred to as interstitial nitrogen.

As shown in FIG. 10A, the state in which the carbon (C) entering the nitrogen site and the interstitial nitrogen coexist is energetically higher than the state in which the interstitial carbon is present alone. The energy in the state where carbon (C) entering the nitrogen site and interstitial nitrogen coexist is 3.0 eV higher than the energy in the state where interstitial carbon is present alone. Therefore, it can be seen that it is difficult to push nitrogen out of the nitrogen site so that carbon enters the nitrogen site to become an acceptor simply by introducing carbon between the lattices.

As a result of the study by the inventors, it has been clarified that when the interstitial carbon coexists with the interstitial hydrogen, carbon is bonded to hydrogen and accordingly easily enters the nitrogen site. FIG. 10B is a diagram for energy difference comparison between a state in which interstitial carbon coexists with interstitial hydrogen (left diagram) and a state in which carbon bonded to hydrogen and entering the nitrogen site coexists with interstitial nitrogen (right diagram). Hereinafter, the carbon bonded to hydrogen and entering the nitrogen site is also referred to as hydrogen-bonded carbon (H-bonded C).

As shown in FIG. 10B, the state in which hydrogen-bonded carbon coexists with interstitial nitrogen is energetically lower than the state in which interstitial carbon coexists with interstitial hydrogen. The energy in the state in which hydrogen-bonded carbon coexists with interstitial nitrogen is 1.0 eV lower than the energy in the state in which interstitial carbon coexists with interstitial hydrogen.

In the semiconductor device manufacturing method of the first embodiment, carbon is implanted into the nitride semiconductor layer 10 by the first ion implantation, and hydrogen is implanted into the nitride semiconductor layer 10 by the second ion implantation. Then, first nitrogen annealing is performed. By the first nitrogen annealing, carbon and hydrogen are bonded to each other in the nitride semiconductor layer 10 to form hydrogen-bonded carbon. Then, the hydrogen-bonded carbon enters the nitrogen site of gallium nitride.

In the semiconductor device manufacturing method of the first embodiment, in particular, the silicon nitride layer 50 is formed as a coating layer on the surface of the nitride semiconductor layer 10. Then, the first nitrogen annealing is performed in a state in which the silicon nitride layer 50 is provided. The first nitrogen annealing is annealing in a state in which the surface of the nitride semiconductor layer 10 is capped (cap annealing). This cap exhibits the effect of retaining hydrogen in the nitride semiconductor layer 10. Therefore, the formation of hydrogen-bonded carbon is promoted, and the hydrogen-bonded carbon efficiently enters the nitrogen site.

In addition, in the semiconductor device manufacturing method of the first embodiment, carbon is introduced into the nitride semiconductor layer 10 by ion implantation. Due to the energy of ion implantation, nitrogen vacancies are formed in gallium nitride. The formation of nitrogen vacancies further promotes carbon entry into the nitrogen site.

According to the semiconductor device manufacturing method of the first embodiment, since carbon and hydrogen are introduced into the nitride semiconductor layer 10, the entry of carbon into the nitrogen site is promoted. Therefore, it is possible to increase the percentage of carbon entering the nitrogen site of gallium nitride.

In addition, the hydrogen-bonded carbon is inert in gallium nitride. Therefore, in order to activate the carbon in gallium nitride, it is necessary to desorb hydrogen from the hydrogen-bonded carbon.

As shown in FIG. 10C, the energy difference between a state in which hydrogen-bonded carbon is present at the nitrogen site (left diagram) and a state in which hydrogen is desorbed from the carbon present at the nitrogen site to become a hydrogen molecule (H₂) (right diagram) is −0.2 eV. The state in which hydrogen is desorbed from the carbon present at the nitrogen site to become a hydrogen molecule (H₂) has lower energy and is more stable than the state in which hydrogen-bonded carbon is present at the nitrogen site. Therefore, it can be seen that hydrogen is easily desorbed from carbon to become a hydrogen molecule (H₂).

In the semiconductor device manufacturing method of the first embodiment, the surface of the nitride semiconductor layer 10 is exposed by removing the silicon nitride layer 50 on the surface of the nitride semiconductor layer 10. In this state, second nitrogen annealing is performed. The second heat treatment is annealing after removing the cap on the surface of the nitride semiconductor layer 10 (capless annealing).

Since the second nitrogen annealing is capless annealing, it is difficult to retain hydrogen in the nitride semiconductor. For this reason, the second nitrogen annealing promotes the outward diffusion of hydrogen in the nitride semiconductor layer 10. Therefore, a state in which hydrogen is desorbed from carbon and carbon enters the nitrogen site, that is, a state in which carbon is activated is realized. This is a state in which carbon is activated as an acceptor in the p-type impurity region.

In the semiconductor device manufacturing method of the first embodiment, carbon is implanted into the nitride semiconductor layer 10 by the first ion implantation. At this time, in addition to nitrogen vacancies, gallium vacancies are formed in gallium nitride by the energy of ion implantation. When carbon enters the formed gallium vacancies, the carbon functions as a donor, which is not preferable.

In the semiconductor device manufacturing method of the first embodiment, gallium is implanted into the nitride semiconductor layer 10 by the third ion implantation. The implanted gallium fills the gallium vacancies during the first heat treatment. Therefore, carbon is suppressed from entering the gallium vacancies, and carbon that functions as a donor is reduced. Therefore, by performing the third ion implantation, it is possible to further increase the percentage of carbon entering the nitrogen site of gallium nitride.

According to the semiconductor device manufacturing method of the first embodiment, for example, the activation rate of carbon contained in the p-type impurity region 10a as an acceptor can be set to be equal to or more than 90%.

In other words, it is possible to set the percentage of carbon atoms that function as acceptors, among all the carbon atoms contained in the p-type impurity region 10a, to be equal to or more than 90%.

As described above, according to the semiconductor device manufacturing method of the first embodiment, carbon is implanted into the nitride semiconductor layer 10 by the first ion implantation, hydrogen is implanted into the nitride semiconductor layer 10 by the second ion implantation, gallium is further implanted into the nitride semiconductor layer 10 by the third ion implantation, and the first heat treatment (cap annealing) and the second heat treatment (capless annealing) are performed. Therefore, since the activation rate of carbon as an acceptor increases, it is possible to form a low-resistance p-type impurity region.

The coating layer preferably contains silicon nitride from the viewpoint of suppressing the outward diffusion of hydrogen from the nitride semiconductor layer 10 and increasing the production efficiency of hydrogen-bonded carbon.

The first heat treatment is preferably performed in an atmosphere containing hydrogen from the viewpoint of suppressing the outward diffusion of hydrogen from the nitride semiconductor layer 10 and increasing the production efficiency of hydrogen-bonded carbon. In addition, it is preferable that the first heat treatment is performed in an atmosphere containing helium. By performing the first heat treatment in an atmosphere containing helium, it is possible to block the passage of hydrogen in the coating layer. As a result, it is possible to suppress the outward diffusion of hydrogen.

The second heat treatment is preferably performed in an atmosphere containing no hydrogen from the viewpoint of promoting the outward diffusion of hydrogen from the nitride semiconductor layer 10. In addition, the second heat treatment is preferably performed at a lower pressure than that in the first heat treatment from the viewpoint of promoting the outward diffusion of hydrogen from the nitride semiconductor layer 10. In addition, the second heat treatment is preferably performed at a pressure lower than the atmospheric pressure from the viewpoint of promoting the outward diffusion of hydrogen from the nitride semiconductor layer 10. In addition, the second heat treatment is preferably performed at a lower partial pressure of hydrogen than that in the first heat treatment from the viewpoint of promoting the outward diffusion of hydrogen from the nitride semiconductor layer 10. In addition, the second heat treatment is preferably performed after the coating layer is removed from the viewpoint of promoting the outward diffusion of hydrogen from the nitride semiconductor layer 10.

From the viewpoint of increasing the production efficiency of hydrogen-bonded carbon in the nitride semiconductor layer 10, the dose amount of hydrogen in the second ion implantation is preferably larger than the dose amount of carbon in the first ion implantation.

From the viewpoint of increasing the production efficiency of hydrogen-bonded carbon in the nitride semiconductor layer 10, it is preferable that the hydrogen concentration distribution formed by the second ion implantation includes the carbon concentration distribution formed by the first ion implantation, as shown in FIG. 5.

From the viewpoint of increasing the production efficiency of hydrogen-bonded carbon in the nitride semiconductor layer 10, the dose amount of hydrogen in the second ion implantation is preferably equal to or more than 1×10¹⁵ cm⁻². Since hydrogen is easily diffused in the c-axis direction (direction perpendicular to the substrate), it is possible to reliably diffuse hydrogen to the position adjacent to the carbon in the first ion implantation by introducing hydrogen with a dose amount equal to or more than 1×10¹⁵ cm⁻². Eventually, hydrogen is discharged to the outside, so that hydrogen does not remain in the gallium nitride to cause a problem. Therefore, a sufficient amount of hydrogen can be introduced without worrying about the residual hydrogen.

The dose amount of hydrogen in the second ion implantation is preferably equal to or less than 1×10¹⁶ cm⁻². Although hydrogen is a light element, if hydrogen is ion-implanted exceeding 1×10¹⁶ cm⁻², there is a risk of slight damage to the substrate. In addition, even if the dose amount of hydrogen in the second ion implantation is equal to or less than 1×10¹⁶ cm⁻², it is possible to sufficiently generate hydrogen-bonded carbon.

From the viewpoint of suppressing the excessive formation of nitrogen vacancies in the nitride semiconductor layer 10, the dose amount of gallium in the third ion implantation is preferably smaller than the dose amount of carbon in the first ion implantation. In addition, the concentration of gallium implanted in the third ion implantation is preferably lower at any position than the concentration of carbon implanted in the first ion implantation.

The nitrogen vacancies in the nitride semiconductor layer 10 function as donors. Therefore, if nitrogen vacancies are excessively formed by the third ion implantation and cannot be filled with carbon, the electrical resistance of the p-type impurity region 10a increases.

From the viewpoint of suppressing the excessive formation of nitrogen vacancies in the nitride semiconductor layer 10, it is preferable that the gallium concentration distribution formed by the third ion implantation is included in the carbon concentration distribution formed by the first ion implantation, as shown in FIG. 4.

In addition, the case where the nitride semiconductor layer 10 is gallium nitride (GaN) has been described as an example, but the same function and effect as in the case of gallium nitride are realized if the nitride semiconductor layer 10 contains “GaN-based semiconductor”, such as AlGaN, AlN, or InGaN.

### Modification Example

A modification example of the semiconductor device manufacturing method of the first embodiment is different from the semiconductor device manufacturing method of the first embodiment in that oxygen (O) is ion-implanted instead of carbon (C) in the first ion implantation. A semiconductor device manufactured by the modification example of the semiconductor device manufacturing method of the first embodiment includes a nitride semiconductor layer having an n-type impurity region.

The semiconductor device manufacturing method of the modification example includes an oxygen ion implantation step as the first ion implantation instead of the carbon ion implantation step S102 (first ion implantation). The impurity region 10a formed by the semiconductor device manufacturing method of the modification example is an n-type impurity region.

Oxygen in gallium nitride is energetically more stable when the oxygen enters the nitrogen site than when the oxygen enters the gallium site in an ideal state in which there are no defects, such as vacancies or interstitial atoms. Oxygen enters the nitrogen site of gallium nitride to function as an n-type impurity, that is, a donor.

However, even if oxygen is introduced into gallium nitride, there is a problem that the electrical resistance of the n-type impurity region containing oxygen does not decrease since the activation rate of oxygen as a donor does not increase. One reason for this problem is considered to be that a part of the oxygen introduced into gallium nitride enters the gallium site.

Oxygen enters the gallium site of gallium nitride to function as a p-type impurity, that is, an acceptor. Therefore, the activation rate of oxygen as a donor is considered to be low eventually. The reason why oxygen enters the gallium site instead of the nitrogen site is considered to be, for example, the presence of gallium vacancies in gallium nitride. In addition, it is considered that when the oxygen of N site, which is an n-type impurity, is formed, self-compensation is likely to occur in which oxygen of Ga site, which is a p-type impurity, is formed at the same time. In this specification, in order to pass through inert hydrogen-bonded oxygen (H-bonded O) when making an n-type impurity, it is possible to finally form the oxygen of N site, which is an n-type impurity, without causing self-compensation.

In order to reduce the electrical resistance of the n-type impurity region containing oxygen, it is necessary to increase the percentage of oxygen entering the nitrogen site of gallium nitride by suppressing oxygen from entering the gallium site of gallium nitride.

As a result of the study by the inventors, as in the case of carbon, it has been clarified that when the interstitial oxygen coexists with the interstitial hydrogen, oxygen is bonded to hydrogen and accordingly easily enters the nitrogen site. Therefore, by replacing carbon with oxygen during the first ion implantation in the semiconductor device manufacturing method of the first embodiment, the same effect as in the case of carbon can also be obtained for oxygen. Therefore, according to the modification example of the semiconductor device manufacturing method of the first embodiment, it is possible to form a low-resistance n-type impurity region by increasing the activation rate of oxygen as a donor.

By the semiconductor device manufacturing method of the modification example, the nitride semiconductor layer 10 having the impurity region 10a is formed. The impurity region 10a is an n-type nitride semiconductor region in which oxygen, which is a conductive impurity, is activated. The impurity region 10a is an n-type impurity region containing oxygen. The oxygen concentration of the impurity region 10a is, for example, equal to or more than 1×10¹⁶ cm⁻³.

According to the modification example of the semiconductor device manufacturing method of the first embodiment, for example, the activation rate of oxygen contained in the n-type impurity region 10a as a donor can be set to equal to or more than 90%. In other words, it is possible to set the percentage of oxygen atoms that function as donors, among all the oxygen atoms contained in the n-type impurity region 10a, to be equal to or more than 90%.

As described above, according to the semiconductor device manufacturing method of the first embodiment and its modification example, it is possible to provide a semiconductor device manufacturing method in which a low-resistance impurity region is locally formed in a nitride semiconductor by using the ion implantation method.

### Second Embodiment

A semiconductor device manufacturing method of a second embodiment includes: performing first ion implantation for implanting an element of either carbon (C) or oxygen (O) into a nitride semiconductor layer; performing second ion implantation for implanting hydrogen (H) into the nitride semiconductor layer; forming a coating layer on a surface of the nitride semiconductor layer;

performing a first heat treatment; and performing a second heat treatment under conditions different from conditions of the first heat treatment.

The semiconductor device manufacturing method of the second embodiment is different from the semiconductor device manufacturing method of the first embodiment in that the coating layer is not removed before the second heat treatment and the conditions of the first heat treatment and the conditions of the second heat treatment are different. Hereinafter, the description of a part of the content overlapping the first embodiment will be omitted.

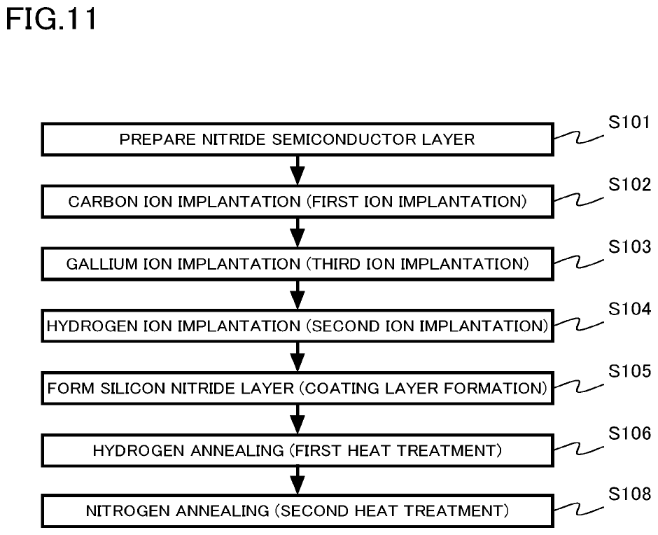

FIG. 11 is a diagram showing the manufacturing flow of a semiconductor device manufacturing method of a second embodiment. The semiconductor device manufactured by the semiconductor device manufacturing method of the second embodiment includes a nitride semiconductor layer having a p-type impurity region.

The semiconductor device manufacturing method of the second embodiment includes a nitride semiconductor layer preparation step S101, a carbon ion implantation step S102 (first ion implantation), a gallium ion implantation step S103 (third ion implantation), a hydrogen ion implantation step S104 (second ion implantation), a silicon nitride layer formation step S105 (coating layer formation), a hydrogen annealing step S106 (first heat treatment), and a nitrogen annealing step S108 (second heat treatment).

In the semiconductor device manufacturing method of the second embodiment, after the first heat treatment, the second heat treatment is performed under the conditions different from those of the first heat treatment without removing the coating layer.

The process up to the formation of the coating layer is the same as that in the semiconductor device manufacturing method of the first embodiment.

Then, hydrogen annealing is performed (S106). The hydrogen annealing is performed, for example, in an atmosphere containing hydrogen under the conditions of temperature equal to or more than 900° C. and equal to or less than 1250° C. The hydrogen annealing is an example of the first heat treatment. The partial pressure of hydrogen in the atmosphere during hydrogen annealing is, for example, 100%.

Then, nitrogen annealing is performed (S108). The nitrogen annealing is performed, for example, in a nitrogen gas atmosphere under the conditions of temperature equal to or more than 900° C. and equal to or less than 1250° C. The nitrogen annealing is an example of the second heat treatment.

The second heat treatment is performed in an atmosphere containing no hydrogen or in an atmosphere having a lower partial pressure of hydrogen than that in the first heat treatment. The second heat treatment is performed in a non-oxidizing atmosphere containing argon, nitrogen, or helium, for example.

In the semiconductor device manufacturing method of the second embodiment, the silicon nitride layer 50 is formed as a coating layer on the surface of the nitride semiconductor layer 10. Then, hydrogen annealing is performed in a state in which the silicon nitride layer 50 is provided. The hydrogen annealing is annealing in a state in which the surface of the nitride semiconductor layer 10 is capped (cap annealing). This cap exhibits the effect of retaining hydrogen in the nitride semiconductor layer 10. In particular, by performing the hydrogen annealing in an atmosphere containing hydrogen, the outward diffusion of hydrogen from the nitride semiconductor layer 10 is suppressed.

In addition, the hydrogen-bonded carbon is inert in gallium nitride. In order to activate the carbon in gallium nitride, it is necessary to desorb hydrogen from the hydrogen-bonded carbon.

In the semiconductor device manufacturing method of the second embodiment, the second heat treatment is performed in an atmosphere containing no hydrogen or in an atmosphere having a partial pressure of hydrogen lower than that in the first heat treatment. Therefore, the outward diffusion of hydrogen in the nitride semiconductor layer 10 is promoted. As a result, a state in which hydrogen is desorbed from the hydrogen-bonded carbon and carbon enters the nitrogen site, that is, a state in which carbon is activated as an acceptor is realized. According to the semiconductor device manufacturing method of the second embodiment, it is possible to form a low-resistance p-type impurity region by increasing the activation rate of carbon as an acceptor.

In addition, similar to the modification example of the semiconductor device manufacturing method of the first embodiment, as a modification example of the semiconductor device manufacturing method of the second embodiment, it is possible to form a low-resistance n-type impurity region by implanting oxygen in the first ion implantation to increase the activation rate of oxygen as a donor.

As described above, according to the semiconductor device manufacturing method of the second embodiment and its modification example, it is possible to provide a semiconductor device manufacturing method in which a low-resistance impurity region is locally formed in a nitride semiconductor by using the ion implantation method.

### Third Embodiment

A semiconductor device manufacturing method of a third embodiment is different from the semiconductor device manufacturing method of the first embodiment in that the coating layer is not removed before the second heat treatment and the conditions of the first heat treatment and the conditions of the second heat treatment are different. In addition, the semiconductor device manufacturing method of the third embodiment is different from the semiconductor device manufacturing method of the second embodiment in that the second heat treatment is performed at a lower pressure than that in the first heat treatment. Hereinafter, the description of a part of the content overlapping the first and second embodiments will be omitted.

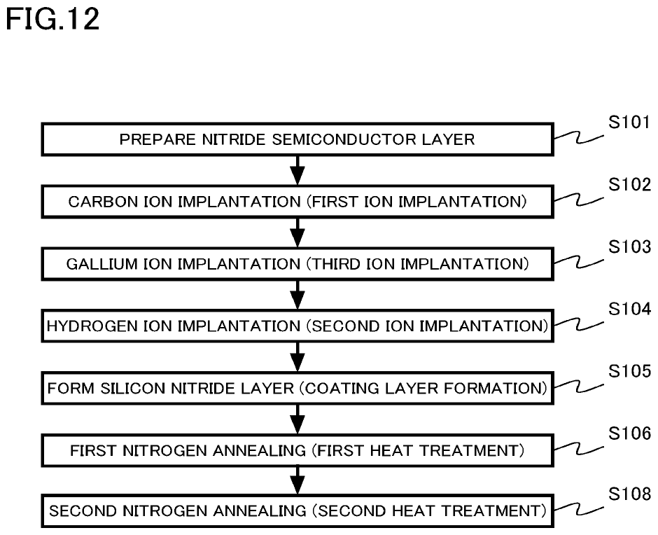

FIG. 12 is a diagram showing the manufacturing flow of a semiconductor device manufacturing method of a third embodiment. The semiconductor device manufactured by the semiconductor device manufacturing method of the third embodiment includes a nitride semiconductor layer having a p-type impurity region.

The semiconductor device manufacturing method of the third embodiment includes a nitride semiconductor layer preparation step S101, a carbon ion implantation step S102 (first ion implantation), a gallium ion implantation step S103 (third ion implantation), a hydrogen ion implantation step S104 (second ion implantation), a silicon nitride layer formation step S105 (coating layer formation), a first nitrogen annealing step S106 (first heat treatment), and a second nitrogen annealing step S108 (second heat treatment).

In the semiconductor device manufacturing method of the third embodiment, after the first heat treatment, the second heat treatment is performed under the conditions different from those of the first heat treatment without removing the coating layer.

The process up to the formation of the coating layer is the same as that in the semiconductor device manufacturing method of the first embodiment.

Then, first nitrogen annealing is performed (S106). The first nitrogen annealing is performed, for example, in a nitrogen gas atmosphere under the conditions of temperature equal to or more than 900° C. and equal to or less than 1250° C. The first nitrogen annealing is performed, for example, at atmospheric pressure. The first nitrogen annealing is an example of the first heat treatment.

The first heat treatment is performed in a non-oxidizing atmosphere containing argon, nitrogen, hydrogen, or helium, for example.

Then, second nitrogen annealing is performed (S108). The second nitrogen annealing is performed at a lower pressure than that in the first nitrogen annealing. The second nitrogen annealing is performed, for example, at a pressure lower than atmospheric pressure. The second nitrogen annealing is performed, for example, in a nitrogen gas atmosphere under the conditions of temperature equal to or more than 900° C. and equal to or less than 1250° C. The second nitrogen annealing is an example of the second heat treatment.

The second heat treatment is performed in a non-oxidizing atmosphere containing argon, nitrogen, or helium, for example. The second heat treatment is performed, for example, in an atmosphere containing no hydrogen.

In the semiconductor device manufacturing method of the third embodiment, the silicon nitride layer 50 is formed as a coating layer on the surface of the nitride semiconductor layer 10. Then, the first nitrogen annealing is performed in a state in which the silicon nitride layer 50 is provided. The first nitrogen annealing is annealing in a state in which the surface of the nitride semiconductor layer 10 is capped (cap annealing). This cap exhibits the effect of retaining hydrogen in the nitride semiconductor layer 10.

In addition, the hydrogen-bonded carbon is inert in gallium nitride. In order to activate the carbon in gallium nitride, it is necessary to desorb hydrogen from the hydrogen-bonded carbon.

In the semiconductor device manufacturing method of the third embodiment, the second heat treatment is performed at a pressure lower than that in the first heat treatment. For example, the first heat treatment is performed at atmospheric pressure, and the second heat treatment is performed at a pressure lower than atmospheric pressure.

Therefore, the outward diffusion of hydrogen in the nitride semiconductor layer 10 is promoted. As a result, a state in which hydrogen is desorbed from the hydrogen-bonded carbon and carbon enters the nitrogen site, that is, a state in which carbon is activated as an acceptor is realized. According to the semiconductor device manufacturing method of the third embodiment, it is possible to form a low-resistance p-type impurity region by increasing the activation rate of carbon as an acceptor.

In addition, similar to the modification example of the semiconductor device manufacturing method of the first embodiment, as a modification example of the semiconductor device manufacturing method of the third embodiment, it is possible to form a low-resistance n-type impurity region by implanting oxygen in the first ion implantation to increase the activation rate of oxygen as a donor.

As described above, according to the semiconductor device manufacturing method of the third embodiment and its modification example, it is possible to provide a semiconductor device manufacturing method in which a low-resistance impurity region is locally formed in a nitride semiconductor by using the ion implantation method.

### Fourth Embodiment

A semiconductor device manufacturing method of a fourth embodiment is different from the semiconductor device manufacturing method of the first embodiment in that the first heat treatment has a first step and a second step subsequent to the first step, heat treatment is performed in a state in which a voltage, at which the side of the coating layer is positive with respect to the side of the nitride semiconductor layer, is applied in the first step, and heat treatment is performed in a state in which a voltage, at which the side of the coating layer is negative with respect to the side of the nitride semiconductor layer, is applied in the second step. Hereinafter, the description of a part of the content overlapping the first embodiment will be omitted.

The semiconductor device manufactured by the semiconductor device manufacturing method of the fourth embodiment includes a nitride semiconductor layer having a p-type impurity region.

The semiconductor device manufacturing method of the fourth embodiment is the same as the semiconductor device manufacturing method of the first embodiment except that the first nitrogen annealing step S106 (first heat treatment) has a first step and a second step.

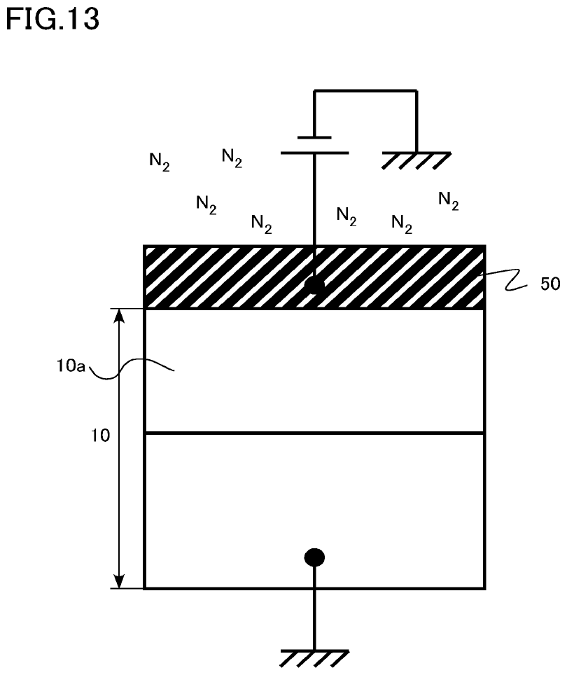

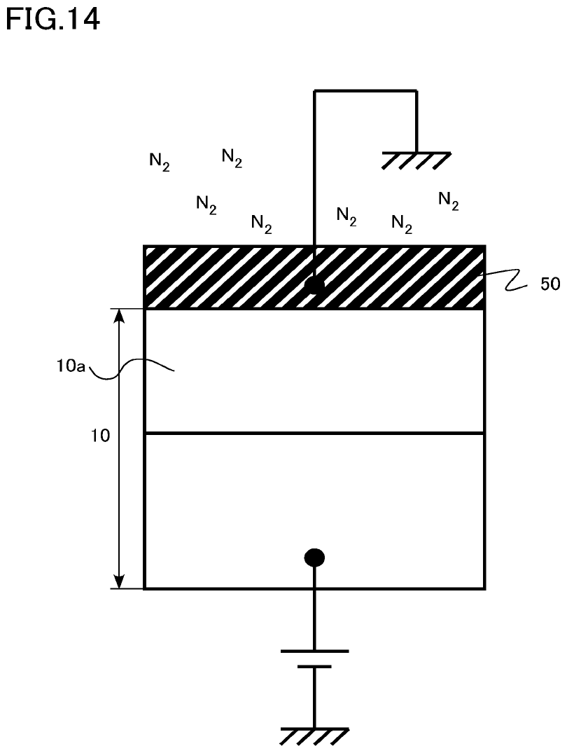

FIGS. 13 and 14 are cross-sectional views showing the semiconductor device manufacturing method of the fourth embodiment. FIG. 13 is an explanatory diagram of the first step of the first heat treatment. FIG. 14 is an explanatory diagram of the second step of the first heat treatment.

The first nitrogen annealing is performed, for example, in a nitrogen gas atmosphere under the conditions of temperature equal to or more than 900° C. and equal to or less than 1250° C. The first nitrogen annealing is an example of the first heat treatment.

The first heat treatment is performed in a non-oxidizing atmosphere containing argon, nitrogen, hydrogen, or helium, for example.

In the first step of the first heat treatment, as shown in FIG. 13, the heat treatment is performed in a state in which a voltage, at which the side of the silicon nitride layer 50 is positive with respect to the side of the nitride semiconductor layer 10, is applied. For example, an electrode is brought into contact with the nitride semiconductor layer 10 and the silicon nitride layer 50 to apply a voltage.

In the second step of the first heat treatment, as shown in FIG. 14, the heat treatment is performed in a state in which a voltage, at which the side of the silicon nitride layer 50 is negative with respect to the side of the nitride semiconductor layer 10, is applied.

In the semiconductor device manufacturing method of the fourth embodiment, before the first heat treatment, hydrogen (H) is ion-implanted into the nitride semiconductor layer 10 by the second ion implantation and gallium (Ga) is ion-implanted into the nitride semiconductor layer 10 by the third ion implantation. In the insulating layer, hydrogen and gallium are positively charged.

In the first step, by applying a voltage at which the side of the silicon nitride layer 50 is positive with respect to the side of the nitride semiconductor layer 10, it is possible to suppress the outward diffusion of hydrogen and gallium in the nitride semiconductor layer 10 through the silicon nitride layer 50. Therefore, the production efficiency of hydrogen-bonded carbon can be increased. In addition, it is possible to prevent carbon from entering the gallium vacancies to become a donor.

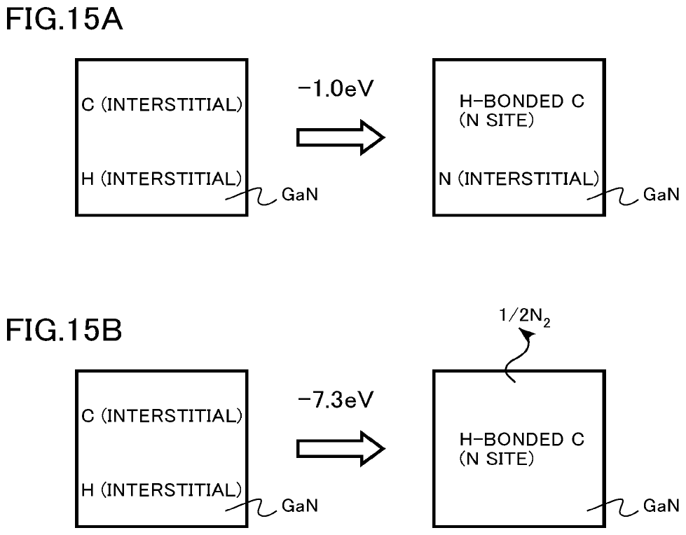

FIGS. 15A and 15B are explanatory diagrams of the function and effect of the semiconductor device manufacturing method of the fourth embodiment. FIGS. 15A and 15B are diagrams showing the results of energy calculation in a state in which carbon is present in gallium nitride (GaN).

FIG. 15A is a diagram for energy difference comparison between a state in which interstitial carbon coexists with interstitial hydrogen (left diagram) and a state in which hydrogen-bonded carbon coexists with interstitial nitrogen (right diagram). FIG. 15A is the same diagram as FIG. 10B.

FIG. 15B is a diagram for energy difference comparison between a state in which interstitial carbon coexists with interstitial hydrogen (left diagram) and a state in which hydrogen-bonded carbon is present (right diagram). That is, the state shown on the right side of FIG. 15B is a state in which nitrogen is diffused outward from the state shown on the right side of FIG. 15A.

The case where nitrogen is diffused outward as shown in FIG. 15B has much lower energy and is more stable than the case where hydrogen-bonded carbon coexists with interstitial nitrogen as shown in FIG. 15A.

Nitrogen in the insulating layer is negatively charged. Therefore, in the first step, by applying a voltage at which the side of the silicon nitride layer 50 is positive with respect to the side of the nitride semiconductor layer 10, it is possible to promote the outward diffusion of nitrogen in the nitride semiconductor layer 10 through the silicon nitride layer 50. As a result, the formation of hydrogen-bonded carbon is promoted.

In addition, in the second step, by applying a voltage at which the side of the silicon nitride layer 50 is negative with respect to the side of the nitride semiconductor layer 10, it is possible to promote the outward diffusion of excess gallium and hydrogen in the nitride semiconductor layer 10 through the silicon nitride layer 50. Excess gallium in the nitride semiconductor layer 10 may degrade the characteristics of the semiconductor device. Therefore, by performing the second step, it is possible to suppress the degradation of the characteristics of the semiconductor device.

According to the semiconductor device manufacturing method of the fourth embodiment, it is possible to form a p-type impurity region having a lower resistance by further increasing the activation rate of carbon as an acceptor. In addition, it is possible to suppress the degradation of the characteristics of the semiconductor device.

In addition, similar to the modification example of the semiconductor device manufacturing method of the first embodiment, as a modification example of the semiconductor device manufacturing method of the fourth embodiment, it is possible to form a low-resistance n-type impurity region by implanting oxygen in the first ion implantation to increase the activation rate of oxygen as a donor.

As described above, according to the semiconductor device manufacturing method of the fourth embodiment and its modification example, it is possible to provide a semiconductor device manufacturing method in which a low-resistance impurity region is locally formed in a nitride semiconductor by using the ion implantation method.

### Fifth Embodiment

A semiconductor device of a fifth embodiment includes: a nitride semiconductor layer; a first nitride semiconductor region of p-type disposed in the nitride semiconductor layer and containing carbon (C) having an activation rate equal to or more than 90% as an acceptor; and a second nitride semiconductor region of n-type disposed in the nitride semiconductor layer and containing oxygen (O) having an activation rate equal to or more than 90% as a donor. The semiconductor device of the fifth embodiment is manufactured by using the semiconductor device manufacturing methods of the first to fourth embodiments.

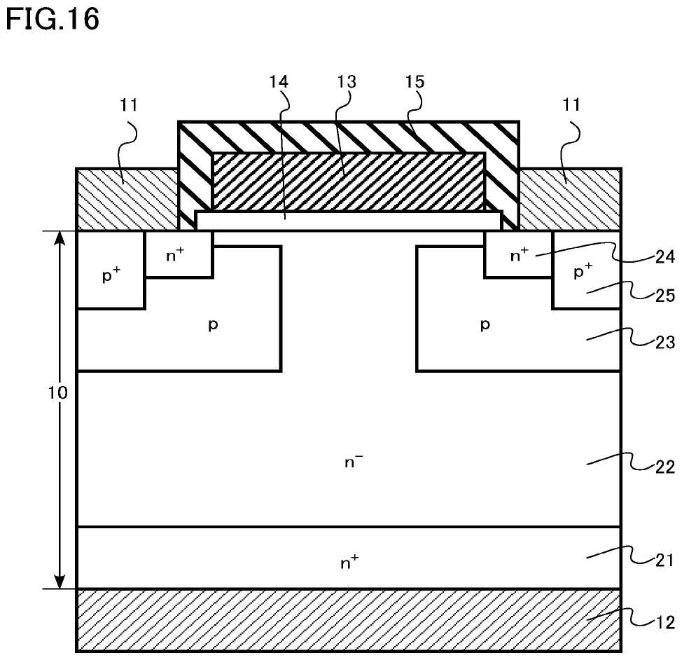

FIG. 16 is a schematic cross-sectional view of the semiconductor device of the fifth embodiment. The semiconductor device of the fifth embodiment is a vertical high electron mobility transistor (HEMT).

The vertical HEMT of the fifth embodiment includes a nitride semiconductor layer 10, a source electrode 11, a drain electrode 12, a gate electrode 13, an aluminum nitride layer 14, and an interlayer insulating layer 15. The nitride semiconductor layer 10 includes an n+-type drain region 21, an n⁻-type drift region 22, a p-type body region 23 (first nitride semiconductor region), an n′-type source region 24 (second nitride semiconductor region, nitride semiconductor region), and a p⁺-type contact region 25 (first nitride semiconductor region).

The nitride semiconductor layer 10 is, for example, gallium nitride.

The p-type body region 23 contains carbon (C) as a p-type impurity. The p-type impurity concentration in the body region 23 is, for example, equal to or more than 1×10¹⁶ cm⁻³ and equal to or less than 1×10¹⁹ cm⁻³. The activation rate of carbon as an acceptor in the body region 23 is equal to or more than 90°. The body region 23 is an example of the first nitride semiconductor region.

The n⁺-type source region 24 contains oxygen (O) as an n-type impurity. The n-type impurity concentration in the source region 24 is, for example, equal to or more than 1×10¹⁸ cm⁻³ and equal to or less than 1×10²¹ cm⁻³. The activation rate of oxygen as a donor in the source region 24 is equal to or more than 90%. The source region 24 is an example of the second nitride semiconductor region or the nitride semiconductor region.

The p-type contact region 25 contains carbon (C) as a p-type impurity. The p-type impurity concentration in the contact region 25 is, for example, equal to or more than 1×10¹⁸ cm⁻³ and equal to or less than 1×10²¹ cm⁻³. The activation rate of carbon as an acceptor in the contact region 25 is equal to or more than 90%. The contact region 25 is an example of the first nitride semiconductor region.

In addition, the activation rate of the impurity region can be calculated by, for example, impurity concentration measurement using secondary ion mass spectrometry (SIMS) and carrier concentration measurement using the Hall effect measurement.

In the body region 23, the source region 24, and the contact region 25, it is possible to realize a high activation rate by using the semiconductor device manufacturing methods of the first to fourth embodiments. By locally forming the p-type impurity region or the n-type impurity region by using the ion implantation method, high performance and low cost are realized.

In the vertical HEMT of the fifth embodiment, it is possible to realize low on-resistance by using a two-dimensional electron gas formed between the drift region 22 and the aluminum nitride layer 14 as a carrier. In addition, by providing the source region 24 having a low resistance, it is possible to realize low on-resistance. In addition, by providing the body region 23 having a high p-type impurity concentration immediately below the gate electrode 13, it is possible to realize a normally-off operation.

### Sixth Embodiment

A semiconductor device of a sixth embodiment includes: a nitride semiconductor layer and a first nitride semiconductor region of p-type disposed in the nitride semiconductor layer and containing carbon (C) having an activation rate equal to or more than 90% as an acceptor. The semiconductor device of the sixth embodiment is manufactured by using the semiconductor device manufacturing methods of the first to fourth embodiments.

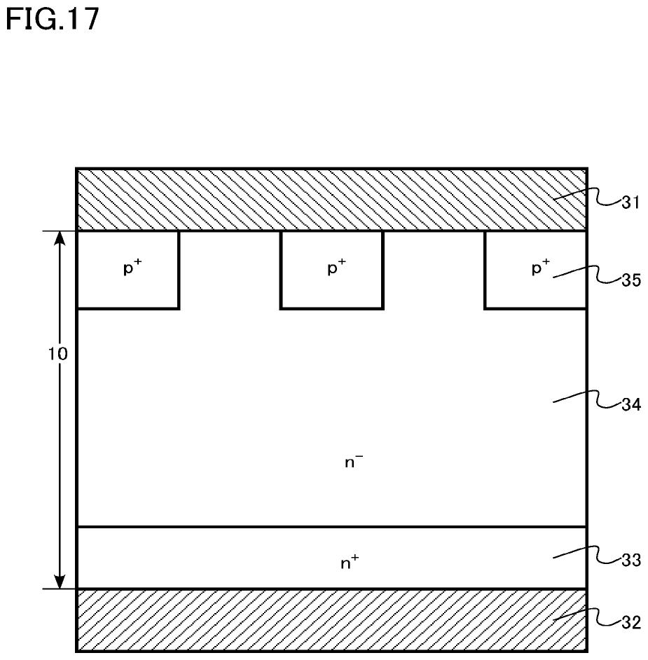

FIG. 17 is a schematic cross-sectional view of the semiconductor device of the sixth embodiment. The semiconductor device of the sixth embodiment is a merged PiN Schottky diode (MPS diode).

The MPS diode of the sixth embodiment includes a nitride semiconductor layer 10, an anode electrode 31, and a cathode electrode 32. The nitride semiconductor layer 10 includes an n+-type region 33, an n⁻-type region 34, and a p⁺-type region 35 (first nitride semiconductor region).

The nitride semiconductor layer 10 is, for example, gallium nitride.

The p⁺-type region 35 contains carbon (C) as a p-type impurity. The p-type impurity concentration in the p⁺-type region 35 is, for example, equal to or more than 1×10¹⁸ cm⁻³ and equal to or less than 1×10²¹ cm⁻³. The activation rate of the p⁺-type region 35 as an acceptor is equal to or more than 90%. The p⁺-type region 35 is an example of the first nitride semiconductor region.

In the p⁺-type region 35, it is possible to realize a high activation rate by using the semiconductor device manufacturing methods of the first to fourth embodiments. By locally forming the p-type impurity region by using the ion implantation method, high performance and low cost are realized.

The MPS diode of the sixth embodiment includes the p⁺-type region 35 having a high p-type impurity concentration, so that the contact resistance between the anode electrode 31 and the p⁺-type region 35 is reduced. Therefore, a large forward current can flow. As a result, high surge current tolerance can be realized.

### Seventh Embodiment

A semiconductor device of a seventh embodiment includes: a nitride semiconductor layer; a first nitride semiconductor region of p-type disposed in the nitride semiconductor layer and containing carbon (C) having an activation rate equal to or more than 90% as an acceptor; and a second nitride semiconductor region of n-type disposed in the nitride semiconductor layer and containing oxygen (O) having an activation rate equal to or more than 90% as a donor. The semiconductor device of the seventh embodiment is manufactured by using the semiconductor device manufacturing methods of the first to fourth embodiments.

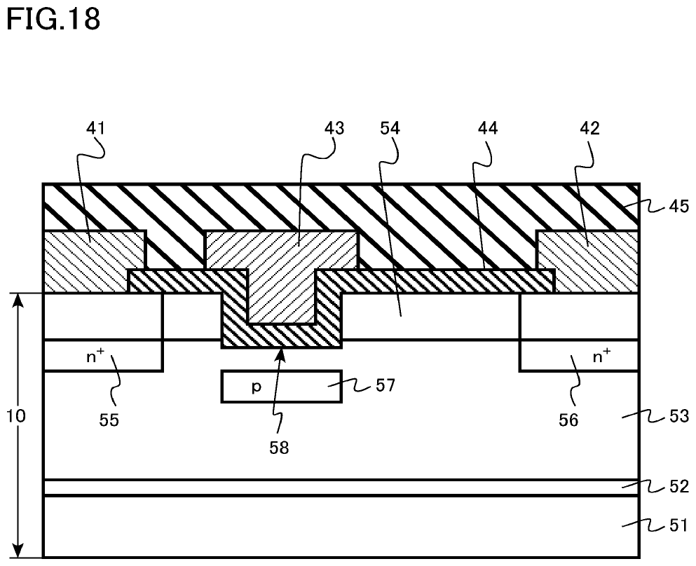

FIG. 18 is a schematic cross-sectional view of the semiconductor device of the seventh embodiment. The semiconductor device of the seventh embodiment is a horizontal HEMT. The horizontal HEMT has a gate recess structure in which a gate electrode is provided in a trench (recess).

The horizontal HEMT of the seventh embodiment includes a nitride semiconductor layer 10, a source electrode 41, a drain electrode 42, a gate electrode 43, a gate insulating layer 44, and an interlayer insulating layer 45. The nitride semiconductor layer 10 includes a substrate 51, a buffer layer 52, a channel layer 53, a barrier layer 54, an n⁺-type source region 55 (second nitride semiconductor region, nitride semiconductor region), an n+-type drain region 56 (second nitride semiconductor region, nitride semiconductor region), a p-type trench bottom region 57 (first nitride semiconductor region), and a trench 58.

The nitride semiconductor layer 10 is, for example, gallium nitride.

The n+-type source region 55 contains oxygen (O) as an n-type impurity. The n-type impurity concentration in the source region 55 is, for example, equal to or more than 1×10¹⁸ cm⁻³ and equal to or less than 1×10²¹ cm⁻³. The activation rate of oxygen as a donor in the source region 55 is equal to or more than 90%. The source region 55 is an example of the second nitride semiconductor region or the nitride semiconductor region.

The n⁺-type drain region 56 contains oxygen (O) as an n-type impurity. The n-type impurity concentration in the drain region 56 is, for example, equal to or more than 1×10¹⁸ cm⁻³ and equal to or less than 1×10²¹ cm⁻³. The activation rate of oxygen as a donor in the drain region 56 is equal to or more than 90%. The drain region 56 is an example of the second nitride semiconductor region or the nitride semiconductor region.

The p-type trench bottom region 57 contains carbon (C) as a p-type impurity. The p-type impurity concentration in the trench bottom region 57 is, for example, equal to or more than 1×10¹⁶ cm⁻³ and equal to or less than 1×10¹⁹ cm⁻³. The activation rate of carbon as an acceptor in the trench bottom region 57 is equal to or more than 90%. The trench bottom region 57 is an example of the first nitride semiconductor region.

In the source region 55, the drain region 56, and the trench bottom region 57, it is possible to realize a high activation rate by using the semiconductor device manufacturing methods of the first to fourth embodiments. By locally forming the p-type impurity region or the n-type impurity region by using the ion implantation method, high performance and low cost are realized.

In the horizontal HEMT of the seventh embodiment, it is possible to realize low on-resistance by using a two-dimensional electron gas formed between the channel layer 53 and the barrier layer 54 as a carrier. In addition, by providing the low-resistance source region 55 and the drain region 56, it is possible to realize low on-resistance. In addition, by providing the trench bottom region 57 having a high p-type impurity concentration immediately below the gate electrode 43, it is possible to increase the threshold voltage.

### Eighth Embodiment

A semiconductor device of an eighth embodiment includes: a nitride semiconductor layer; a first nitride semiconductor region of p-type disposed in the nitride semiconductor layer and containing carbon (C) having an activation rate equal to or more than 90% as an acceptor; and a second nitride semiconductor region of n-type disposed in the nitride semiconductor layer and containing oxygen (O) having an activation rate equal to or more than 90% as a donor. The semiconductor device of the eighth embodiment is manufactured by using the semiconductor device manufacturing methods of the first to fourth embodiments.

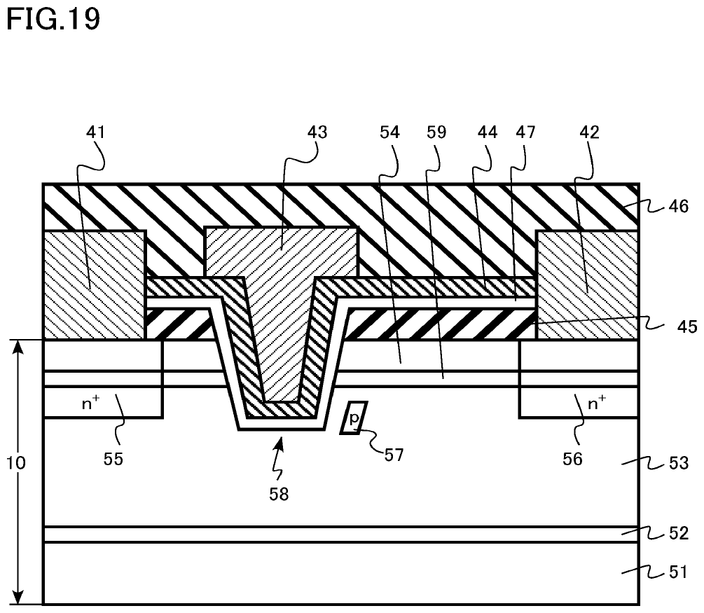

FIG. 19 is a schematic cross-sectional view of the semiconductor device of the eighth embodiment. The semiconductor device of the eighth embodiment is a horizontal HEMT. The horizontal HEMT has a gate recess structure in which a gate electrode is provided in a trench (recess).

The horizontal HEMT of the eighth embodiment includes a nitride semiconductor layer 10, a source electrode 41, a drain electrode 42, a gate electrode 43, a gate insulating layer 44, a first interlayer insulating layer 45, a second interlayer insulating layer 46, and a first aluminum nitride layer 47. The nitride semiconductor layer 10 includes a substrate 51, a buffer layer 52, a channel layer 53, a barrier layer 54, an n′-type source region 55 (second nitride semiconductor region, nitride semiconductor region), an n⁺-type drain region 56 (second nitride semiconductor region, nitride semiconductor region), a p-type trench bottom region 57 (first nitride semiconductor region), a trench 58, and a second aluminum nitride layer 59.

The nitride semiconductor layer 10 is, for example, gallium nitride.

The n⁺-type source region 55 contains oxygen (O) as an n-type impurity. The n-type impurity concentration in the source region 55 is, for example, equal to or more than 1×10¹⁸ cm⁻³ and equal to or less than 1×10²¹ cm⁻³. The activation rate of oxygen as a donor in the source region 55 is equal to or more than 90%. The source region 55 is an example of the second nitride semiconductor region or the nitride semiconductor region.

The n⁺-type drain region 56 contains oxygen (O) as an n-type impurity. The n-type impurity concentration in the drain region 56 is, for example, equal to or more than 1×10¹⁸ cm⁻³ and equal to or less than 1×10²¹ cm⁻³. The activation rate of oxygen as a donor in the drain region 56 is equal to or more than 90%. The drain region 56 is an example of the second nitride semiconductor region or the nitride semiconductor region.

The p-type trench bottom region 57 contains carbon (C) as a p-type impurity. The p-type impurity concentration in the trench bottom region 57 is, for example, equal to or more than 1×10¹⁶ cm⁻³ and equal to or less than 1×10¹⁹ cm⁻³. The activation rate of carbon as an acceptor in the trench bottom region 57 is equal to or more than 90%. The trench bottom region 57 is an example of the first nitride semiconductor region.

In the source region 55, the drain region 56, and the trench bottom region 57, it is possible to realize a high activation rate by using the semiconductor device manufacturing methods of the first to fourth embodiments. By locally forming the p-type impurity region or the n-type impurity region by using the ion implantation method, high performance and low cost are realized.

The horizontal HEMT of the eighth embodiment has a heterojunction interface between the second aluminum nitride layer 59 and the channel layer 53. Two-dimensional electron gas is formed at the heterojunction interface to serve as a carrier. Therefore, low on-resistance can be realized. In addition, by providing the low-resistance source region 55 and the drain region 56, the contact resistance to the two-dimensional electron gas is reduced, so that low on-resistance can be realized. In addition, by providing the trench bottom region 57 having a high p-type impurity concentration, it is possible to increase the threshold voltage. The trench bottom region 57 is at least a part of a region from the side surface near the trench bottom to the bottom surface.

In the fifth to eighth embodiments, the HEMT or the diode has been described as an example of the semiconductor device. However, embodiments can also be applied to other semiconductor devices. For example, embodiments can also be applied to an optical semiconductor device, such as a light emitting diode (LED).

While certain embodiments have been described, these embodiments have been presented by way of example only, and are not intended to limit the scope of the inventions. Indeed, the semiconductor device manufacturing method and the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device manufacturing method, comprising:
performing first ion implantation implanting an element of either carbon (C) or oxygen (O) into a nitride semiconductor layer;
performing second ion implantation implanting hydrogen (H) into the nitride semiconductor layer;
forming a coating layer on a surface of the nitride semiconductor layer;
performing a first heat treatment;
removing the coating layer; and
performing a second heat treatment.

2. The method according to claim 1,
wherein a dose amount of hydrogen in the second ion implantation is larger than a dose amount of the element of either carbon or oxygen in the first ion implantation.

3. The method according to claim 1,
wherein a concentration distribution of hydrogen formed by the second ion implantation includes a concentration distribution of the element of either carbon or oxygen formed by the first ion implantation.

4. The method according to claim 1, further comprising:
performing third ion implantation implanting gallium (Ga) into the nitride semiconductor layer before the forming the coating layer.

5. The method according to claim 4,
wherein a dose amount of gallium in the third ion implantation is smaller than a dose amount of the element of either carbon or oxygen in the first ion implantation.

6. The method according to claim 4,
wherein a concentration distribution of gallium formed by the third ion implantation is included in a concentration distribution of the element of either carbon or oxygen formed by the first ion implantation.

7. The method according to claim 1,
wherein a dose amount of the element of either carbon or oxygen in the first ion implantation is equal to or more than 1×10¹¹ cm⁻² and equal to or less than 1×10¹⁵ cm⁻².

8. The method according to claim 1,
wherein a dose amount of hydrogen in the second ion implantation is equal to or more than 1×10¹⁵ cm⁻².

9. The semiconductor device manufacturing method according to claim 1,
wherein the second heat treatment is performed at a pressure lower than a pressure in the first heat treatment.

10. The method according to claim 1,
wherein the coating layer contains silicon nitride.

11. The method according to claim 1,
wherein the first heat treatment includes a first step and a second step subsequent to the first step,
in the first step, heat treatment is performed with a voltage having a side of the coating layer as positive with respect to a side of the nitride semiconductor layer being applied, and
in the second step, heat treatment is performed with a voltage having a side of the coating layer as negative with respect to a side of the nitride semiconductor layer being applied.

12. A method, comprising:
performing first ion implantation implanting an element of either carbon (C) or oxygen (O) into a nitride semiconductor layer;
performing second ion implantation implanting hydrogen (H) into the nitride semiconductor layer;
forming a coating layer on a surface of the nitride semiconductor layer;
performing a first heat treatment; and
performing a second heat treatment under conditions different from conditions of the first heat treatment.

13. The semiconductor device manufacturing method according to claim 12, further comprising:
performing third ion implantation implanting gallium (Ga) into the nitride semiconductor layer before the forming the coating layer.

14. The method according to claim 12,
wherein the first heat treatment is performed in an atmosphere containing hydrogen, and
the second heat treatment is performed in an atmosphere containing no hydrogen or in an atmosphere having a partial pressure of hydrogen lower than a partial pressure of hydrogen in the first heat treatment.

15. The method according to claim 12,
wherein the second heat treatment is performed at a pressure lower than a pressure in the first heat treatment.

16. A semiconductor device, comprising:
a nitride semiconductor layer; and
a first nitride semiconductor region of p-type disposed in the nitride semiconductor layer and containing carbon (C) having an activation rate equal to or more than 90% as an acceptor.

17. The semiconductor device according to claim 16,
wherein a carbon concentration in the first nitride semiconductor region is equal to or more than 1×10¹⁶ cm⁻³.

18. The semiconductor device according to claim 16, further comprising:
a second nitride semiconductor region of n-type disposed in the nitride semiconductor layer and containing oxygen (O) having an activation rate equal to or more than 90° as a donor.

19. A semiconductor device, comprising:
a nitride semiconductor layer; and
a nitride semiconductor region of n-type disposed in the nitride semiconductor layer and containing oxygen (O) having an activation rate equal to or more than 90% as a donor.

20. The semiconductor device according to claim 19,
wherein an oxygen concentration in the nitride semiconductor region is equal to or more than 1×10¹⁶ cm⁻³.
